(19) United States
(12) Patent Application Publication
(10) Pub. No.: US 2020/0243302 A1
(43) Pub. Date: Jul. 30, 2020

(54) SiC MEMBER AND MANUFACTURING METHOD THEREOF

(71) Applicant: ADMAP INC., Tamano-shi, Okayama (JP)

(72) Inventor: Shimpei CHIDA, Tamano-shi (JP)

(73) Assignee: ADMAP INC., Tamano-shi, Okayama (JP)

(21) Appl. No.: 16/603,698

(22) PCT Filed: Apr. 24, 2019
(86) PCT No.: PCT/JP2019/017416

§ 371 Date: Oct. 8, 2019

(30) Foreign Application Priority Data
Jun. 27, 2018 (JP) 2018-121520

(51) Int. Cl. H01J 37/32; C23C 16/32

(52) U.S. Cl. CPC H01J 37/3244; H01J 2237/334; C23C 16/325; H01J 37/32642

(57) ABSTRACT

A SiC member includes: a substrate having a reference hole in a front-back direction; and first and second SiC coats. The first SiC coat has a first hole connected to the reference hole in the front-back direction, a first region extending around the first hole to form its inner circumferential surface, and a second region extending around the first region adjacently to the first region, the second SiC coat has a second hole connected to the first hole in the front-back direction, a third region extending around the second hole to form its inner circumferential surface, and a fourth region extending around the third region adjacently to the third region, the first region has a crystal structure containing crystals grown in a first direction obliquely crossing the front-back direction, and the second, third and fourth regions have crystal structures containing crystals grown in a second direction along the front-back direction.

### FIELD OF THE INVENTION

The present invention relates to a SiC member containing SiC and a manufacturing method thereof.

### BACKGROUND OF THE INVENTION

A SiC coat containing silicon carbide (SiC) has excellent properties such as high durability, high acid resistance, and low specific resistance, and is widely used as a component for a semiconductor manufacturing apparatus. For example, Patent Document 1 discusses a technique of using the SiC member as an etcher ring or a showerhead in a plasma etching apparatus.

### CITATION LIST

### Patent Documents

Patent Document 1: Japanese Unexamined Patent Application Publication No. 2008-252045

### SUMMARY OF THE INVENTION

In a wafer treatment apparatus, a product defect may occur in a SiC wafer due to even a slight processing variation. In addition, since the wafer treatment apparatus is used to treat a large number of SiC wafers in a semiconductor manufacturing factory, a problem of the product defect may spread to a large number of SiC wafers without limiting to only a single SiC wafer. Therefore, it is essential that the SiC member as a consumable item of the wafer treatment apparatus satisfies the requirement such as durability or an impurity concentration. However, if a pattern derived from a crystal structure or a layer structure appears on the surface of the SiC member, an end user of the wafer treatment apparatus may be worried about a failure in some cases.

For example, in the technique of Patent Document 1, the SiC member has a SiC layer provided on a surface of a showerhead used in a plasma etching apparatus.

In the technique of Patent Document 1, since the showerhead is repeatedly used in the plasma etching apparatus, the SiC layer on the surface is deteriorated. In order to recover the deteriorated SiC layer, the deteriorated SiC layer is grinded, and the SiC layer is formed again on that surface. Such a showerhead is necessary to have a plurality of through-holes extending from the front face to the back face, and the SiC layer is formed again while the through-holes are provided. For this reason, the SiC layer having a crystal structure containing crystals grown in different directions is formed on the surface around the through-hole of the SiC member. As a result, a black dot pattern may appear around the through-hole of the SiC member.

In view of such problems, the present invention provides a technology for easily securing favorable appearance of the SiC member.

In order to address the aforementioned problems, according to the first aspect, there is provided a SiC member having a front side and a back side, including: a substrate having a reference hole penetrating in a front-back direction; a first SiC coat provided at least on a surface on the front side of the substrate; and a second SiC coat provided on a surface on the front side of the first SiC coat, wherein the first SiC coat has a first hole connected to the reference hole in the front-back direction, a first region extending around the first hole to form an inner circumferential surface of the first hole, and a second region extending around the first region adjacently to the first region, the second SiC coat has a second hole connected to the first hole in the front-back direction, a third region extending around the second hole to form an inner circumferential surface of the second hole, and a fourth region extending around the third region adjacently to the third region, the first region has a crystal structure containing crystals grown in a first direction obliquely crossing the front-back direction, and the second region, the third region, and the fourth region have crystal structures containing crystals grown in a second direction along the front-back direction.

In this aspect, the first SiC coat includes the first region having a crystal structure containing crystals grown in the first direction obliquely crossing the front-back direction and the second region having a crystal structure containing crystals grown in the second direction along the front-back direction. In addition, the second SiC coat includes the third and fourth regions having crystal structures containing crystals grown in the second direction along the front-back direction. As a result, the first SiC coat including the first and second regions having crystal structures containing crystals grown in different directions can be covered with the second SiC coat including the third and fourth regions having crystal structures containing crystals grown in a predetermined direction. For this reason, the SiC coat having the crystal structure containing crystals grown in a predetermined direction appears on the surface of the SiC member. As a result, it is possible to prevent a black dot pattern appearing on the surface of the SiC member and easily secure favorable appearance of the SiC member. The first and second SiC coats may be different films formed through different processes. Furthermore, the first and second SiC coats may be upper and lower parts of a single film formed in a single process.

According to the second aspect, it is conceivable that the SiC member is a showerhead provided with a plurality of through-holes penetrating in the front-back direction, and the reference hole, the first hole, and the second hole form one of the plurality of through-holes.

In this aspect, the SiC coat having the crystal structure containing crystals grown in a predetermined direction appears on the surface of the showerhead. As a result, it is possible to prevent a black dot pattern appearing on the surface of the showerhead.

As a method of manufacturing the aforementioned SiC member, the third aspect is conceivable.

According to the third aspect, a manufacturing method for a SiC member includes: preparing a substrate having a reference hole penetrating in the front-back direction; forming a first SiC coat at least on a surface on the front side of the substrate; and forming a second SiC coat on a surface on the front side of the first SiC coat. The first SiC coat has a first hole connected to the reference hole in the front-back direction, a first region extending around the first hole to form an inner circumferential surface of the first hole, and a second region extending around the first region adjacently to the first region. The second SiC coat has a second hole connected to the first hole in the front-back direction, a third region extending around the second hole to form an inner circumferential surface of the second hole, and a fourth region extending around the third region adjacently to the third region. The first region has a crystal structure containing crystals grown in a first direction obliquely crossing the front-back direction. The second region, the third region, and the fourth region have crystal structures containing crystals grown in a second direction along the front-back direction.

In this aspect, the first SiC coat includes the first region having a crystal structure containing crystals grown in the first direction obliquely crossing the front-back direction and the second region having a crystal structure containing crystals grown in the second direction along the front-back direction. In addition, the second SiC coat includes the third and fourth regions having crystal structures containing crystals grown in the second direction along the front-back direction. As a result, the first SiC coat including the first and second regions having crystal structures containing crystals grown in different directions can be covered with the second SiC coat including the third and fourth regions having crystal structures containing crystals grown in a predetermined direction. For this reason, the SiC coat having the crystal structure containing crystals grown in a predetermined direction appears on the surface of the SiC member. As a result, it is possible to provide a manufacturing method for a SiC member, capable of preventing a black dot pattern appearing on the surface of the SiC member.

In the aforementioned manufacturing method, it is necessary to set how to manufacture the first and second holes. For this purpose, the fourth aspect is further conceivable as described below.

According to the fourth aspect, it is conceivable that the forming of the first SiC coat includes forming a first SiC layer by depositing a SiC material on the surface on the front side of the substrate, and forming the first hole by removing the first SiC layer provided in a fifth region connected to the reference hole in the front-back direction, and the forming of the second SiC coat includes forming a second SiC layer by depositing the SiC material on the surface on the front side of the first SiC coat, and forming the second hole by removing the second SiC layer provided in a sixth region connected to the fifth region in the front-back direction.

In this aspect, the first SiC layer is formed on the surface on the front side of the substrate, and the first hole is formed by removing the first SiC layer provided in the fifth region connected to the reference hole in the front-back direction. In addition, the second SiC layer is formed on the surface on the front side of the first SiC layer, and the second hole is formed by removing the second SiC layer provided in the sixth region connected to the fifth region in the front-back direction. As a result, it is possible to easily obtain the first and second holes connected to the reference hole in the front-back direction without applying a mask processing to the region connected to the inner circumferential surface of the reference hole in the front-back direction in advance. As a result, it is possible to provide an easy manufacturing method for the SiC member, capable of preventing a black dot pattern appearing on the surface of the SiC member.

According to the fifth aspect, it is conceivable that the first SiC layer is formed to include an inner circumferential surface of the reference hole, and the fifth region is formed to include the inner circumferential surface of the reference hole.

In this aspect, the first SiC layer is formed to include the surface on the front side of the substrate and the inner circumferential surface of the reference hole. In addition, the first hole is formed by removing the first SiC layer provided in the fifth region including the inner circumferential surface of the reference hole and the region connected to the inner circumferential surface of the reference hole in the front-back direction. Therefore, it is possible to easily obtain the first and second holes connected to the reference hole in the front-back direction without applying a mask processing to the inner circumferential surface of the reference hole in advance. As a result, it is possible to provide an easy manufacturing method for the SiC member, capable of preventing a black dot pattern appearing on the surface of the SiC member.

According to the sixth aspect, it is conceivable that the first SiC layer is formed to close the reference hole.

In this aspect, the first SiC layer is formed to close the reference hole of the substrate. As a result, it is possible to form the surface on the front side of the first SiC layer flat along the surface on the front side of the substrate. For this reason, it is possible to prevent crystals of the crystal structure of the second SiC layer provided on the surface on the front side of the first SiC layer from being grown in the first direction obliquely crossing the front-back direction due to an undulation of the surface on the front side of the first SiC layer. As a result, it is possible to provide an easy manufacturing method for the SiC member, capable of preventing a black dot pattern appearing on the surface of the SiC member.

According to the seventh aspect, it is conceivable that the forming of the first hole and the forming of the second hole include removing the fifth region of the first SiC layer and the sixth region of the second SiC layer after forming the second SiC layer.

In this aspect, the first and second holes are formed after the second SiC layer is formed. Therefore, only the crystal structure containing crystals grown in the second direction along the front-back direction appears on the front side of the SiC member. As a result, it is possible to provide an easy manufacturing method for the SiC member, capable of preventing a black dot pattern appearing on the surface of the SiC member.

### BRIEF DESCRIPTION OF DRAWINGS

FIG. 1 is a perspective view illustrating a structure of a SiC member according to an embodiment of the invention;

FIG. 2 is a schematic cross-sectional view taken along the line A-A of the SiC member according to an embodiment of the invention;

FIG. 3 is an enlarged view illustrating one of through-holes of the SiC member according to an embodiment of the invention;

FIG. 4 is a diagram illustrating crystal growth directions in a first SiC layer around a reference hole of the SiC member according to an embodiment of the invention;

FIG. 5 is a diagram illustrating crystal growth directions in first and second SiC layers around the reference hole of the SiC member according to an embodiment of the invention;

FIG. 6 is a diagram illustrating fifth and sixth regions of the SiC member according to an embodiment of the invention; and

FIG. 7 is a photograph showing dots appearing on a surface of the SiC member.

### DESCRIPTION OF EMBODIMENTS

Embodiments of the present invention will now be described with reference to the accompanying drawings.

### (1) General Configuration

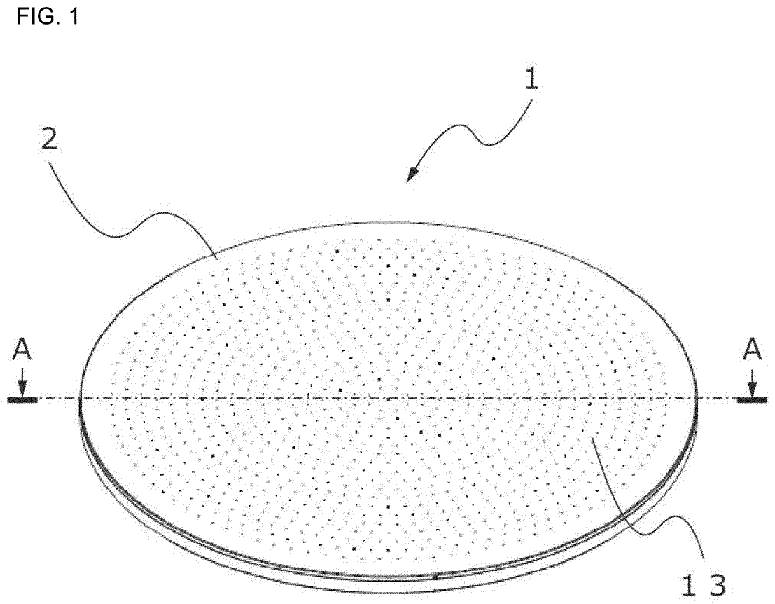

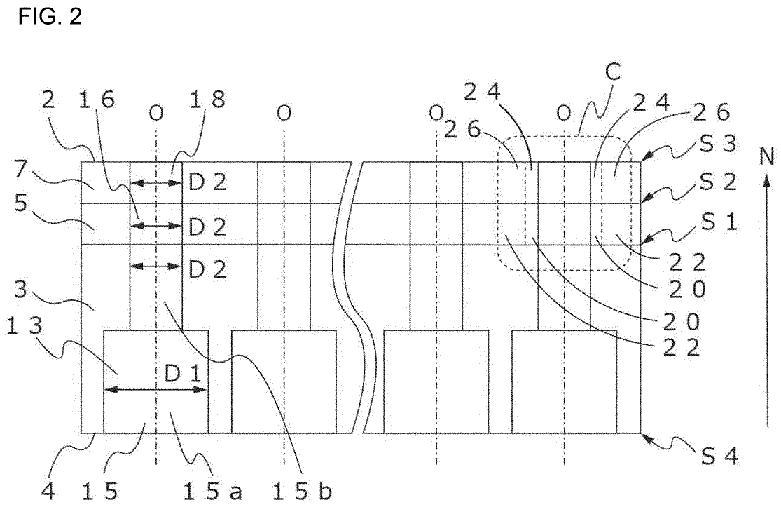

A SiC member 1 includes a substrate 3, a first SiC coat 5, and a second SiC coat 7. As illustrated in FIGS. 1 and 2, the SiC member 1 has a front side 2 and a back side 4, and a plurality of through-holes 13 are arranged to penetrate from the front side 2 to the back side 4. According to this embodiment, the SiC member 1 is a showerhead that discharges a reactant gas or an inert gas into a processing chamber in a plasma treatment apparatus used in an etching process or a film formation process of a semiconductor manufacturing procedure. In addition, the through-hole 13 is a gas injection hole of the showerhead as the SiC member 1, through which the reactant gas or the inert gas passes. Note that, in the following description, the direction directed from the back side 4 to the front side 2 will be referred to as a “front-back direction N”.

The substrate 3 has a surface S1 on a front side, a surface S4 on a back side, and a reference hole 15. The reference hole 15 penetrates the substrate 3 from the surface S4 on the back side to the surface S1 on the front side in the front-back direction N. The reference hole 15 includes a first reference hole 15a arranged on the back side 4 and a second reference hole 15b arranged on the surface S1 side on the front side of the substrate 3. For example, the first reference hole 15a is formed in a cylindrical shape having a diameter D1 and a center O. The second reference hole 15b is formed in a cylindrical shape having a diameter D2 smaller than the diameter D1 of the first reference hole 15a and a center O concentric to the first reference hole 15a. According to this embodiment, the diameter D1 is set to approximately 1 to 2 mm, and the diameter D2 is set to approximately 0.5 to 1 mm. On the surface S1 on the front side of the substrate 3, a first SiC coat 5 is formed. The surface S4 on the back side of the substrate 3 serves as the back side 4 of the SiC member 1.

The first SiC coat 5 has a surface S2 on a front side, a first hole 16, a first region 20, and a second region 22. The first SiC coat 5 is formed of CVD-SiC produced using chemical vapor deposition (CVD).

The first hole 16 is connected to the reference hole 15 in the front-back direction N. The first hole 16 is formed, for example, in a cylindrical shape having the same diameter D1 as that of the second reference hole 15b and the center O concentric to the first and second reference holes 15a and 15b.

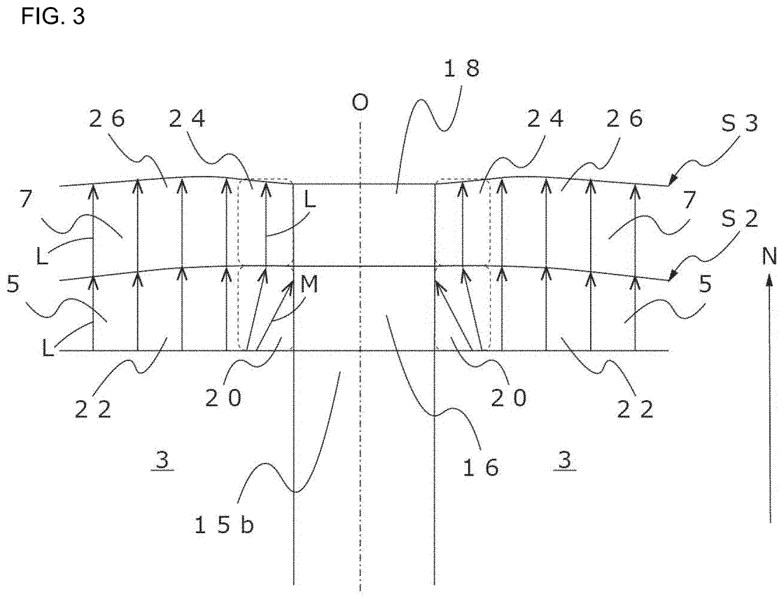

FIG. 3 is an enlarged view illustrating a portion C of FIG. 2 as one of the through-holes 13. In FIG. 3, the arrows indicate directions of SiC crystal growth in the CVD method. As illustrated in FIG. 3, the first region 20 forms an inner circumferential surface of the first hole 16 and extends around the first hole 16. In addition, the first region 20 has a crystal structure containing crystals grown in a first direction M obliquely crossing the front-back direction N.

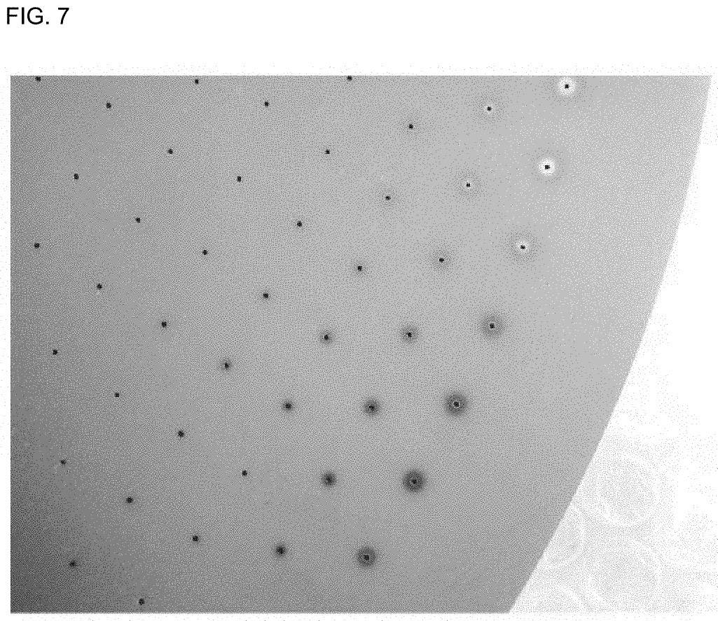

The second region 22 extends around the first region adjacently to the first region 20. The second region 22 has a crystal structure containing crystals grown in a second direction L along the front-back direction N. For this reason, a crystal structure containing crystals grown in different directions appears on the surface S2 on the front side of the first SiC coat 5. The inventors found that dots appear as illustrated in FIG. 7 if an oxidation process is applied in this state after the surface S2 on the front side is fabricated. In this regard, the second SiC coat 7 is formed on the surface S2 on the front side of the first SiC coat 5 so as to cover the crystal structure containing crystals grown in directions different from that of the surface S2 on the front side as illustrated in FIGS. 2 and 3.

As illustrated in FIG. 2, the second SiC coat 7 has a surface S3 on a front side, a second hole 18, a third region 24, and a fourth region 26. The second SiC coat 7 is formed of CVD-SiC produced using the CVD method. According to this embodiment, the surface S3 on the front side of the second SiC coat 7 corresponds to the front side 2 of the SiC member 1.

The second hole 18 is connected to the first hole 16 in the front-back direction N. The second hole 18 is formed, for example, in a cylindrical shape having the same diameter D2 as that of the second reference hole 15b and the center O concentric to the first and second reference holes 15a and 15b. That is, the reference hole 15 and the first and second holes 16 and 18 form one of a plurality of through-holes 13 of the SiC member 1.

As illustrated in FIG. 3, the third region 24 forms an inner circumferential surface of the second hole 18 and extends around the second hole. The fourth region 26 extends around the third region adjacently to the third region 24. The third and fourth regions 24 and 26 include crystal structures containing crystals grown in the second direction L along the front-back direction. That is, the second SiC coat 7 has third and fourth regions 24 and 26 having a crystal structure containing crystals grown in a predetermined direction. For this reason, a crystal structure containing crystals grown in a predetermined direction appears on the surface S3 on the front side of the second SiC coat 7, that is, the front side 2 of the SiC member 1.

### (2) Manufacturing Method

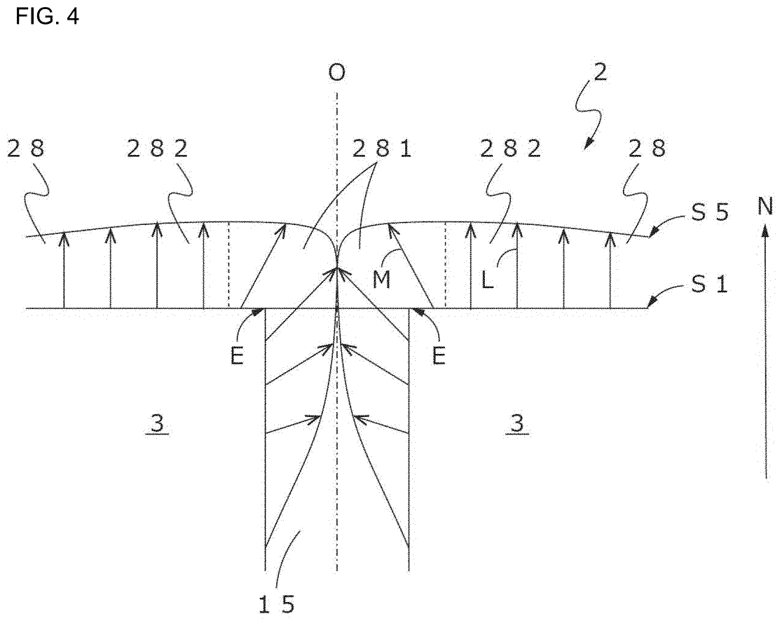

FIGS. 4 to 6 are enlarged views illustrating the portion C of FIG. 2 as one of the through-holes 13. In FIGS. 4 to 6, the arrows indicate directions of growing SiC crystals, that is, crystal growth directions of the crystal structure using the CVD method.

The SiC member 1 may be manufactured in the following procedure. First, a substrate 3 having the reference hole 15 penetrating in the front-back direction N is prepared. According to this embodiment, the substrate 3 is a showerhead having a SiC layer whose surface is deteriorated because it has been used several times in a plasma treatment apparatus for an etching process or a film formation process of a semiconductor manufacturing procedure. In this case, the substrate 3 is prepared by removing the deteriorated SiC layer by mechanically grinding the surface S1 on the front side and the surface S4 on the back side (not shown).

As the substrate 3 is prepared, the SiC material is deposited on the surface S1 on the front side of the substrate 3 to form the first SiC layer 28 including the CVD-SiC layer using the CVD method as illustrated in FIG. 4. The first SiC layer 28 is formed by growing SiC crystals from the surface S1 on the front side of the substrate 3 and the inner circumferential surface of the reference hole 15 to match the shape of the substrate 3. The first SiC layer 28 is formed to include a first portion 281 and a second portion 282.

The first portion 281 is a part of the CVD-SiC layer formed to extend around an edge E as a boundary between the reference hole 15 of the substrate 3 and the surface S1 on the front side from the inner circumferential surface of the reference hole 15 of the substrate 3. The first portion 281 is formed by growing the SiC crystals toward the center O of the reference hole 15 of the substrate 3. That is, the first portion 281 is formed to include a crystal structure containing crystals grown in the first direction M obliquely crossing the front-back direction N. In addition, the first portion 281 is formed to close the reference hole 15. That is, the first portion 281 is provided by forming the CVD-SiC layer to the center O of the reference hole 15. As a result, the surface on the front side 2 of the first portion 281 can be formed flat along the surface approximately parallel to the surface S1 on the front side of the substrate 3.

The second portion 282 is a part of the CVD-SiC layer formed adjacently to the first portion 281 on the surface S1 on the front side of the substrate 3. The second portion 282 is formed by growing the SiC crystals vertically to the surface S1 on the front side of the substrate 3. That is, the second portion 282 includes a crystal structure containing crystals grown in the second direction L along the front-back direction N. In addition, the second portion 282 is formed by depositing the CVD-SiC layer while forming a surface approximately parallel to the surface S1 on the front side of the substrate 3. As a result, the surface on the front side 2 of the second portion 282 can be formed flat along the surface approximately parallel to the surface S1 on the front side of the substrate 3.

As a result, the surface S5 on the front side of the first SiC layer 28 can be formed flat along the surface S1 on the front side of the substrate 3. In addition, the first SiC layer 28 is formed to include the inner circumferential surface of the reference hole 15. Furthermore, the first SiC layer 28 is formed to close the reference hole 15.

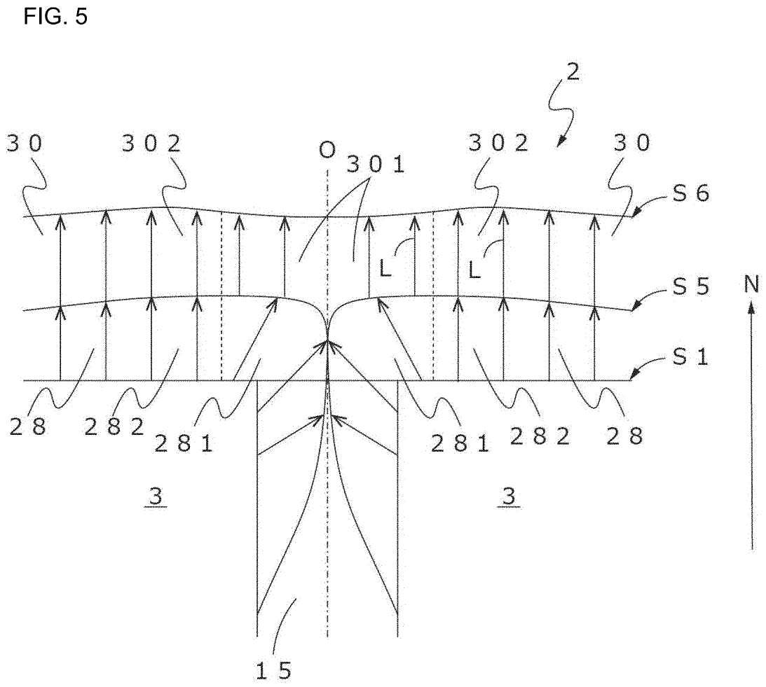

As the first SiC layer 28 is formed, a SiC material is deposited on the surface S5 on the front side of the first SiC layer 28 using the CVD method to form a second SiC layer 30 formed of the CVD-SiC layer as illustrated in FIG. 5. The second SiC layer 30 is formed by growing SiC crystals from the surface S5 on the front side of the first SiC layer 28 along the shape of the surface S5 on the front side. The second SiC layer 30 is formed to include the third portion 301 and the fourth portion 302.

The third portion 301 is a part of the CVD-SiC layer of the first portion 281 of the first SiC layer 28 formed on the surface on the front side 2. The third portion 301 is formed by growing SiC crystals vertically to the surface on the front side 2 of the first portion 281 of the first SiC layer 28. That is, the third portion 301 is formed to include the crystal structure containing crystals grown in the second direction L along the front-back direction N. In addition, the third portion 301 is formed by depositing the CVD-SiC layer while forming a surface approximately parallel to the surface S1 on the front side of the substrate 3. As a result, the surface on the front side 2 of the third portion 301 can be formed flat along a surface approximately parallel to the surface S5 on the front side of the first SiC layer 28.

The fourth portion 302 is a part of the CVD-SiC layer formed adjacently to the third portion 301 on the surface on the front side 2 of the second portion 282 of the first SiC layer 28. The fourth portion 302 is formed by growing SiC crystals vertically to the surface on the front side 2 of the second portion 282 of the first SiC layer 28. That is, the fourth portion 302 includes a crystal structure containing crystals grown in the second direction L along the front-back direction N. Furthermore, the fourth portion 302 is formed by depositing the CVD-SiC layer while forming a surface approximately parallel to the surface S1 on the front side of the substrate 3. As a result, the surface on the front side 2 of the fourth portion 302 can be formed flat along a surface approximately parallel to the surface S5 on the front side of the first SiC layer 28. For this reason, the surface S6 on the front side of the second SiC layer can be formed flat along a surface approximately parallel to the surface S5 on the front side of the first SiC layer 28.

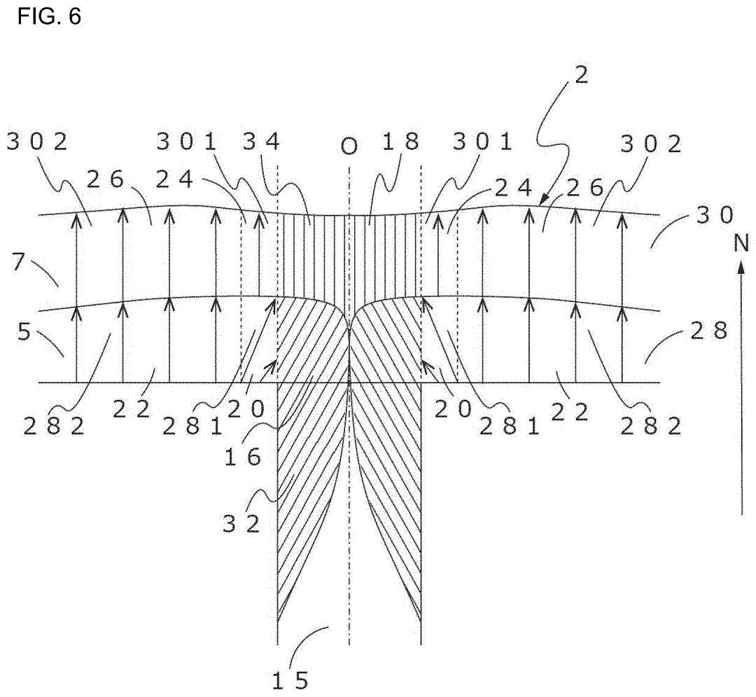

As the second SiC layer 30 is formed, the first hole 16 is formed by removing the first SiC layer 28 formed in the fifth region 32 connected to the reference hole 15 in the front-back direction N as illustrated in FIG. 6. In addition, the second hole 18 is formed by removing the second SiC layer 30 provided in the sixth region 34 connected to the fifth region 32 in the front-back direction N. According to this embodiment, the first and second holes 16 and 18 are formed by mechanical machining such as ultrasonic machining. The material surface on the front side 2 of the second SiC layer 30 is cut out to form the surface on the front side 2 of the SiC member 1.

The fifth region 32 is a region of the first SiC layer 28 connected to the reference hole 15 in the front-back direction N. That is, the fifth region 32 is a part of the first portion 281 of the first SiC layer 28. If the first SiC layer 28 formed in the fifth region 32 is removed, a part of the first portion 281 of the first SiC layer 28 and the second portion 282 remain. This part of the first portion 281 forms the inner circumferential surface of the first hole 16 and becomes the first region 20 extending around the first hole 16. In addition, the second portion 282 becomes the second region 22 extending around the first region 20 adjacently to the first region 20.

The first SiC layer 28 finally remaining through such a manufacturing method is formed as the first SiC coat 5 including the first hole 16 connected to the reference hole 15 in the front-back direction N, the first region 20 extending around the first hole 16 to form the inner circumferential surface of the first hole 16, and the second region 22 extending around the first region 20 adjacently to the first region 20.

The sixth region 34 is a region of the second SiC layer 30 connected to the fifth region 32 in the front-back direction N. That is, the sixth region 34 is a part of the third portion 301 of the second SiC layer 30. If the second SiC layer 30 formed in the sixth region 34 is removed, a part of the third portion 301 of the second SiC layer 30 and the fourth portion 302 remain. This part of the third portion 301 forms the inner circumferential surface of the second hole 18 and becomes a third region 24 extending around the second hole 18. Furthermore, the fourth portion 302 becomes a fourth region 26 extending around the third region 24 adjacently to the third region 24.

The second SiC layer 30 finally remaining through such a manufacturing method is formed as the second SiC coat 7 including the second hole 18 connected to the first hole 16 in the front-back direction N, the third region 24 extending around the second hole 18 to form the inner circumferential surface of the second hole 18, and the fourth region 26 extending around the third region 24 adjacently to the third region 24.

### (3) Modifications

Needless to say, various forms may be possible within the technical scope of the invention without limiting the embodiments of the invention to the aforementioned examples.

For example, in the aforementioned embodiment, a showerhead used in a plasma treatment apparatus provided with through-holes 13 has been exemplified as the SiC member 1. However, the SiC member is not limited to the showerhead, but may have any other shape as long as the reference hole is provided.

### (4) Advantages and Effects

In this configuration, the first SiC coat 5 includes the first region 20 having a crystal structure containing crystals grown in the first direction M obliquely crossing the front-back direction N and the second region 22 having a crystal structure containing crystals grown in the second direction L along the front-back direction N. In addition, the second SiC coat 7 includes the third region 24 and the fourth region 26 having crystal structures containing crystals grown in the second direction L along the front-back direction N. As a result, the first SiC coat 5 having the first and second regions 20 and 22 having crystal structures containing crystals grown in different directions can be covered with the second SiC coat 7 including the third and fourth regions 24 and 26 having crystal structures containing crystals grown in a predetermined direction. For this reason, a SiC coat having a crystal structure containing crystals grown in a predetermined direction appears on the surface of the SiC member 1. As a result, it is possible to prevent a black dot pattern appearing on the surface of the SiC member 1 and easily secure favorable appearance of the SiC member.

In this configuration, the SiC coat having a crystal structure containing crystals grown in a predetermined direction appears on the surface of the showerhead which is the SiC member 1. As a result, it is possible to prevent a black dot pattern appearing on the surface of the showerhead.

In this manufacturing method, the first SiC coat 5 includes the first region 20 having a crystal structure containing crystals grown in the first direction M obliquely crossing the front-back direction N and the second region 22 having a crystal structure containing crystals grown in the second direction L along the front-back direction N. In addition, the second SiC coat 7 includes the third and fourth regions 24 and 26 having crystal structures containing crystals grown in the second direction L along the front-back direction N. As a result, the first SiC coat 5 including the first and second regions 20 and 22 having crystal structures containing crystals grown in different directions can be covered with the second SiC coat 7 including the third and fourth regions 24 and 26 having crystal structures containing crystals grown in a predetermined direction. For this reason, the SiC coat having a crystal structure containing crystals grown in the predetermined direction appears on the surface of the SiC member 1. As a result, it is possible to provide a manufacturing method for the SiC member 1, capable of preventing a black dot pattern appearing on the surface of the SiC member 1 and easily securing favorable appearance of the SiC member 1.

In the aforementioned manufacturing method, the first SiC layer 28 is formed on the surface S1 on the front side of the substrate 3, and the first hole 16 is formed by removing the first SiC layer 28 provided in the fifth region 32 connected to the reference hole 15 in the front-back direction N. In addition, the second SiC layer 30 is provided on the surface S5 on the front side of the first SiC layer 28, and the second hole 18 is formed by removing the second SiC layer 30 provided in the sixth region 34 connected to the fifth region 32 in the front-back direction N. As a result, it is possible to easily obtain the first and second holes 16 and 18 connected to the reference hole 15 in the front-back direction N without applying a mask processing to the region connected to the reference hole 15 in the front-back direction N in advance. As a result, it is possible to provide an easy manufacturing method for the SiC member 1, capable of preventing a black dot pattern appearing on the surface of the SiC member 1.

In the aforementioned manufacturing method, the first SiC layer 28 is formed to include the surface S1 on the front side of the substrate 3 and the inner circumferential surface of the reference hole 15. In addition, the first hole 16 is formed by removing the first SiC layer 28 provided in the fifth region 32 including the inner circumferential surface of the reference hole 15 and the region connected to the inner circumferential surface of the reference hole 15 in the front-back direction N. As a result, it is possible to easily obtain the first and second holes 16 and 18 connected to the reference hole 15 in the front-back direction N without applying a mask processing to the inner circumferential surface of the reference hole 15 in advance.

In the aforementioned manufacturing method, the first SiC layer 28 is formed to close the reference hole 15 of the substrate 3. As a result, it is possible to form the surface S5 on the front side of the first SiC layer 28 flat along the surface S1 on the front side of the substrate 3. For this reason, it is possible to prevent crystals of the crystal structure of the second SiC layer 30 provided on the surface S5 on the front side of the first SiC layer 28 from being grown in the first direction M obliquely crossing the front-back direction N due to an undulation on the surface S5 on the front side of the first SiC layer 28. As a result, it is possible to provide an easy manufacturing method for the SiC member 1, capable of preventing a black dot pattern appearing on the surface of the SiC member 1.

In the aforementioned manufacturing method, the first and second holes 16 and 18 are formed after forming the second SiC layer 30. Therefore, only the crystal structure containing crystals grown in the second direction L along the front-back direction N appears on the front side 2 of the SiC member 1. As a result, it is possible to provide an easy manufacturing method for the SiC member 1, capable of preventing a black dot pattern appearing on the surface of the SiC member 1.

### REFERENCE SIGNS LIST

1 SiC member,
2 front side,
3 substrate,
4 back side,
5 first SiC coat,
7 second SiC coat,
13 through-hole,
15 reference hole,
16 first hole,
18 second hole,
20 first region,
22 second region,
24 third region,
26 fourth region,
28 first SiC layer,
30 second SiC layer,
32 fifth region,
34 sixth region,
S1 surface on front side of substrate 3,
S2 surface on front side of first SiC coat,
S3 surface on front side of second SiC coat,
M first direction,
L second direction.

1. A SiC member having a front side and a back side, comprising:
a substrate having a reference hole penetrating in a front-back direction;
a first SiC coat provided at least on a surface on the front side of the substrate; and
a second SiC coat provided on a surface on the front side of the first SiC coat,
wherein the first SiC coat has
a first hole connected to the reference hole in the front-back direction,
a first region extending around the first hole to form an inner circumferential surface of the first hole, and
a second region extending around the first region adjacently to the first region,
the second SiC coat has
a second hole connected to the first hole in the front-back direction,
a third region extending around the second hole to form an inner circumferential surface of the second hole, and
a fourth region extending around the third region adjacently to the third region,
the first region has a crystal structure containing crystals grown in a first direction obliquely crossing the front-back direction, and
the second region, the third region, and the fourth region have crystal structures containing crystals grown in a second direction along the front-back direction.

2. The SiC member according to claim 1, wherein the SiC member is a showerhead provided with a plurality of through-holes penetrating in the front-back direction, and
the reference hole, the first hole, and the second hole form one of the plurality of through-holes.

3. A manufacturing method for a SiC member having a front side and a back side, the method comprising:
preparing a substrate having a reference hole penetrating in a front-back direction;
forming a first SiC coat at least on a surface on the front side of the substrate; and
forming a second SiC coat on a surface on the front side of the first SiC coat,
wherein the first SiC coat has
a first hole connected to the reference hole in the front-back direction,
a first region extending around the first hole to form an inner circumferential surface of the first hole, and
a second region extending around the first region adjacently to the first region,
the second SiC coat has
a second hole connected to the first hole in the front-back direction,
a third region extending around the second hole to form an inner circumferential surface of the second hole, and
a fourth region extending around the third region adjacently to the third region,
the first region has a crystal structure containing crystals grown in a first direction obliquely crossing the front-back direction, and
the second region, the third region, and the fourth region have crystal structures containing crystals grown in a second direction along the front-back direction.

4. The manufacturing method according to claim 3, wherein the forming of the first SiC coat includes:
forming a first SiC layer by depositing a SiC material on the surface on the front side of the substrate; and
forming the first hole by removing the first SiC layer provided in a fifth region connected to the reference hole in the front-back direction, and
the forming of the second SiC coat includes:
forming a second SiC layer by depositing the SiC material on the surface on the front side of the first SiC coat; and
forming the second hole by removing the second SiC layer provided in a sixth region connected to the fifth region in the front-back direction.

5. The manufacturing method according to claim 4, wherein
the first SiC layer is formed to include an inner circumferential surface of the reference hole, and
the fifth region is formed to include the inner circumferential surface of the reference hole.

6. The manufacturing method according to claim 4, wherein
the first SiC layer is formed to close the reference hole.

7. The manufacturing method according to claim 4, wherein
the forming of the first hole and the forming of the second hole include removing the fifth region of the first SiC layer and the sixth region of the second SiC layer after forming the second SiC layer.

8. The manufacturing method according to claim 5, wherein
the first SiC layer is formed to close the reference hole.

9. The manufacturing method according to claim 5, wherein
the forming of the first hole and the forming of the second hole include removing the fifth region of the first SiC layer and the sixth region of the second SiC layer after forming the second SiC layer.

10. The manufacturing method according to claim 6, wherein
the forming of the first hole and the forming of the second hole include removing the fifth region of the first SiC layer and the sixth region of the second SiC layer after forming the second SiC layer.

11. The manufacturing method according to claim 8, wherein
the forming of the first hole and the forming of the second hole include removing the fifth region of the first SiC layer and the sixth region of the second SiC layer after forming the second SiC layer.
